(19) United States
(12) Patent Application Publication
(10) Pub. No.: US 2024/0096679 A1
(43) Pub. Date: Mar. 21, 2024

(54) SUBSTRATE LOADING DEVICE AND SUBSTRATE LOADING METHOD USING THE SAME

(71) Applicant: Samsung Display Co., LTD., Yongin-si (KR)

(72) Inventors: JUNHYEUK KO, Yongin-si (KR); MINGOO KANG, Yongin-si (KR); MINSEOK KIM, Yongin-si (KR); MINCHUL SONG, Yongin-si (KR); Sukha Ryu, Yongin-si (KR); EUIGYU KIM, Yongin-si (KR)

(73) Assignee: Samsung Display Co., LTD., Yongin-si (KR)

(21) Appl. No.: 18/469,684

(22) Filed: Sep. 19, 2023

(30) Foreign Application Priority Data
Sep. 20, 2022 (KR) 10-2022-0118878

(51) Int. Cl. H01L 21/683; H01L 21/68

(52) U.S. Cl. CPC H01L 21/6833; H01L 21/682

(57) ABSTRACT

A substrate loading device includes an electrostatic chuck that chucks a substrate, a mask frame disposed under the electrostatic chuck, and including an edge having a flat top surface, and a plurality of holders disposed between the electrostatic chuck and the mask frame. Each of the plurality of holders includes a first connection part connected to a side of the electrostatic chuck, a second connection part connected to the first connection part and extending in a direction intersecting an extension direction of the first connection part, and a third connection part connected to the second connection part, extending in a direction intersecting an extension direction of the second connection part, and rotationally moving between a first position overlapping the substrate in a thickness direction of the substrate and a second position spaced apart from the substrate.

### CROSS-REFERENCE TO RELATED APPLICATION(S)

This application claims priority to and benefits of Korean Patent Application No. 10-2022-0118878 under 35 U.S.C. § 119 filed on Sep. 20, 2022, in the Korean Intellectual Property Office (KIPO), the entire content of which are incorporated herein by reference.

### BACKGROUND

### 1. Technical Field

The disclosure relates to a substrate loading device including electrostatic chuck and a substrate loading method using the substrate loading device.

### 2. Description of the Related Art

A display device is a device configured to display an image for providing visual information to a user. Display devices have been variously used from displays of small products such as mobile phones to displays of large products such as televisions.

A process of manufacturing the display device may include a thin film deposition process of forming a thin film on a surface of a substrate, a photolithography process of exposing a selected portion of the thin film to a light, an etching process of removing the exposed portion of the thin film, and the like.

The thin film deposition process may be performed in a vacuum chamber. An electrostatic chuck (ESC) and a holder may be disposed in the vacuum chamber.

The holder may move the substrate to make close contact with the electrostatic chuck. The electrostatic chuck may chuck the substrate by using an electrostatic force. After the electrostatic chuck making close contact with the substrate is aligned with a mask, deposition materials may be deposited on the substrate through a hole formed in the mask.

### SUMMARY

The disclosure may provide a substrate loading device.

The disclosure may provide a substrate loading method using the and a substrate loading device.

A substrate loading device according to an embodiment of the disclosure may include an electrostatic chuck that chucks a substrate, a mask frame disposed under the electrostatic chuck, and including an edge having a flat top surface, and a plurality of holders disposed between the electrostatic chuck and the mask frame. Each of the plurality of holders may include a first connection part connected to a side of the electrostatic chuck, a second connection part connected to the first connection part and extending in a direction intersecting an extension direction of the first connection part, and a third connection connected to the second connection part, extending in a direction intersecting an extension direction of the second connection part, and rotationally moving between a first position overlapping the substrate in a thickness direction of the substrate and a second position spaced apart from the substrate.

In an embodiment, the third connection part may rotate about the extension direction of the second connection part.

In an embodiment, the third connection part and the second connection part may be integral with each other. The second connection part may rotate about the extension direction of the second connection part.

In an embodiment, the third connection part may linearly move in the extension direction of the second connection part.

In an embodiment, in case that a first surface of the substrate is chucked by the electrostatic chuck, a second surface of the substrate facing the first surface may overlap the mask frame in the thickness direction, and the third connection part may be disposed at the second position not overlapping the mask frame in the thickness direction.

A substrate loading device according to another embodiment of the disclosure may include an electrostatic chuck that chucks a substrate and having an area that is greater than an area of the substrate in a plan view, and a plurality of holders disposed under the electrostatic chuck. Each of the plurality of holders may include a first connection part connected to a side of the electrostatic chuck, a second connection part connected to the first connection part and extending in a direction intersecting an extension direction of the first connection part, and a third connection part connected to the second connection part, extending in a direction intersecting an extension direction of the second connection part, and linearly moving between a first position overlapping the substrate in a thickness direction of the substrate and a second position spaced apart from the substrate.

In an embodiment, the electrostatic chuck may include a groove on a surface facing the substrate adjacent to the plurality of holders. The groove may overlap the third connection part disposed at the second position in the thickness direction.

In an embodiment, the third connection part may linearly move in the direction intersecting the extension direction of the second connection part.

In an embodiment, the substrate loading device may further include a mask frame disposed under the plurality of holders and including an edge having a flat top surface.

In an embodiment, in case that a first surface of the substrate may be chucked by the electrostatic chuck, a second surface of the substrate facing the first surface may overlap the mask frame in the thickness direction, and the third connection part may be disposed at the second position not overlapping the mask frame in the thickness direction.

A substrate loading method according to an embodiment of the disclosure may include holding a substrate by a third connection part of a plurality of holders, which is disposed at a first position overlapping the substrate in a thickness direction of the substrate, each of the plurality of holders including a first connection part connected to a side of the electrostatic chuck, a second connection part connected to the first connection part and extending in a direction intersecting an extension direction of the first connection part, and a third connection part connected to the second connection part and extending in a direction intersecting an extension direction of the second connection part, moving the substrate to closely contact the electrostatic chuck by the plurality of holders, chucking the substrate by the electrostatic chuck, moving the third connection part from the first position to a second position spaced apart from the substrate, moving the third connection part from the second position to the first position, dechucking the substrate by the electrostatic chuck, and holding the substrate by the plurality of holders.

In an embodiment, the moving of the third connection part from the first position to the second position may include rotating the third connection part about the extension direction of the second connection part.

In an embodiment, after the rotating of the third connection part, a distance between ends of third connection parts of the plurality of holders facing each other in an extension direction of the third connection part may be longest.

In an embodiment, the substrate loading method may further include, between the chucking of the substrate by the electrostatic chuck and the moving of the third connection part from the first position to the second position, aligning the substrate with a mask frame disposed under the plurality of holders and including an edge having a flat top surface.

In an embodiment, the substrate loading method may further include, between the moving of the third connection part from the first position to the second position and the moving of the third connection part from the second position to the first position, aligning the substrate with a mask frame disposed under the plurality of holders and including an edge having a flat top surface, and performing a treatment process on the substrate.

In an embodiment, in the performing of the treatment process on the substrate, a first surface of the substrate may be chucked by the electrostatic chuck, a second surface of the substrate facing the first surface may overlap the mask frame in the thickness direction, and the third connection part may not overlap the mask frame in the thickness direction.

In an embodiment, the performing of the treatment process on the substrate may include depositing a deposition material, which is provided from a deposition source disposed under the mask frame, on the substrate.

In an embodiment, the moving of the third connection part from the first position to the second position may include linearly moving the third connection part in an extension direction of the third connection part so that a distance between ends of third connection parts of the plurality of holders facing each other in the extension direction of the third connection part is greater than a width of the mask frame in the extension direction of the third connection part.

In an embodiment, the moving of the third connection part from the first position to the second position may further include linearly moving the third connection part in the extension direction of the second connection part after the linearly moving of the third connection part in the extension direction of the third connection part.

In an embodiment, the substrate loading method may further include, between the linearly moving of the third connection part in the extension direction of the second connection part and the aligning of the substrate with the mask frame, seating the third connection part in grooves formed on the electrostatic chuck.

According to an embodiment of the disclosure, the substrate loading device may include a third connection part that is rotationally movable, so that the plurality of holders including the third connection part and the substrate do not overlap each other in a thickness direction of the substrate. Accordingly, the dead space, which is a portion of the substrate overlapping the holders in the thickness direction, may not exist, and efficiency of the cell arrangement may be increased.

According to an embodiment of the disclosure, the substrate loading device may include a third connection part connected to the electrostatic chuck having a greater area than the substrate in a plan view and linearly movable, so that the plurality of holders including the third connection part and the substrate may not overlap each other in a thickness direction of the substrate. Accordingly, the dead space, which is a portion of the substrate overlapping the holders in the thickness direction, may not exist, and the efficiency of the cell arrangement may be increased.

According to the substrate loading method of the embodiments of the disclosure, the third connection part may rotationally move to the second position spaced apart from the substrate. Accordingly, during the deposition process, the substrate and the mask frame may make close contact with each other, and the manufacturing quality of the display device may be improved.

According to the substrate loading method of the embodiments of the disclosure, the third connection part may linearly move to the second position spaced apart from the substrate. Accordingly, during the deposition process, the substrate and the mask frame may make close contact with each other, and the manufacturing quality of the display device may be improved.

### BRIEF DESCRIPTION OF THE DRAWINGS

Illustrative, non-limiting embodiments will be more clearly understood from the following detailed description in conjunction with the accompanying drawings.

FIG. 1 is a schematic cross-sectional view showing a substrate loading device according to an embodiment of the disclosure.

FIG. 2 is a perspective view for describing a mask frame included in the substrate loading device of FIG. 1.

FIGS. 3 to 12 are schematic cross-views for describing a substrate loading method using the substrate loading device according to an embodiment of the disclosure.

FIG. 13 is an enlarged view showing region A of FIG. 5.

FIG. 14 is an enlarged view showing region A′ of FIG. 7.

FIGS. 15 and 16 are plan views for describing a first position and a second position of the third connection parts.

FIG. 17 is a schematic cross-sectional view showing a substrate loading device according to another embodiment of the disclosure.

FIGS. 18 to 26 are schematic cross-views for describing a substrate loading method using the substrate loading device according to an embodiment of the disclosure.

FIGS. 27 and 28 are plan views for describing a first position and a second position of the third connection parts.

FIG. 29 is a schematic cross-sectional view showing a pixel on which a deposition process is completed by using the substrate loading method according to the embodiments of the disclosure.

### DETAILED DESCRIPTION OF THE EMBODIMENTS

In the following description, for the purposes of explanation, numerous specific details are set forth in order to provide a thorough understanding of various embodiments or implementations of the invention.

When an element, such as a layer, is referred to as being “on”, “connected to”, or “coupled to” another element or layer, it may be directly on, connected to, or coupled to the other element or layer or intervening elements or layers may be present. When, however, an element or layer is referred to as being “directly on”, “directly connected to”, or “directly coupled to” another element or layer, there are no intervening elements or layers present. To this end, the term “connected” may refer to physical, electrical, and/or fluid connection, with or without intervening elements.

In the specification and the claims, the phrase “at least one of” is intended to include the meaning of “at least one selected from the group of” for the purpose of its meaning and interpretation. For example, “at least one of A and B” may be understood to mean “A, B, or A and B.” In the specification and the claims, the term “and/or” is intended to include any combination of the terms “and” and “or” for the purpose of its meaning and interpretation. For example, “A and/or B” may be understood to mean “A, B, or A and B.” The terms “and” and “or” may be used in the conjunctive or disjunctive sense and may be understood to be equivalent to “and/or.” Also, when an element is referred to as being “in contact” or “contacted” or the like to another element, the element may be in “electrical contact” or in “physical contact” with another element; or in “indirect contact” or in “direct contact” with another element.

Unless otherwise defined or implied herein, all terms (including technical and scientific terms) used have the same meaning as commonly understood by those skilled in the art to which this disclosure pertains. It will be further understood that terms, such as those defined in commonly used dictionaries, should be interpreted as having a meaning that is consistent with their meaning in the context of the relevant art and should not be interpreted in an ideal or excessively formal sense unless clearly defined in the specification.

Hereinafter, embodiments of the disclosure will be described in more detail with reference to the accompanying drawings. The same or similar reference numerals are used for the same components in the drawings, and redundant descriptions of the same components will be omitted.

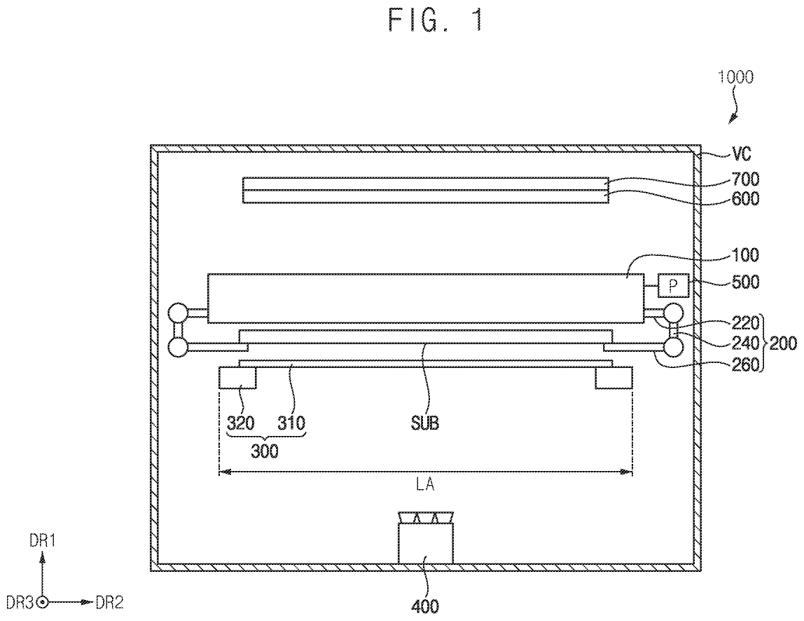

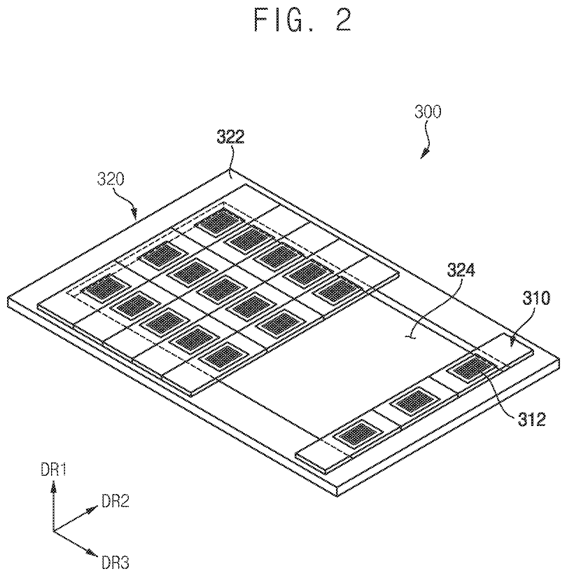

FIG. 1 is a schematic cross-sectional view showing a substrate loading device according to an embodiment of the disclosure, and FIG. 2 is a perspective view for describing a mask frame included in the substrate loading device of FIG. 1.

Referring to FIGS. 1 and 2, a substrate loading device 1000 may include an electrostatic chuck 100, a mask unit 300, a deposition source 400, a cooling plate 600, and a magnetic plate 700 within a vacuum chamber VC.

The vacuum chamber VC may provide an airtight space, and a deposition condition may be set to vacuum. The vacuum chamber VC may include a top surface, a bottom surface, and side surfaces. The bottom surface may face the top surface in a first direction DR1. Each of the side surfaces may be perpendicularly connected to the top and bottom surfaces. At least one gate may be disposed in the vacuum chamber VC. A substrate SUB may enter and exit the vacuum chamber VC through the gate.

The electrostatic chuck 100 may be disposed inside the vacuum chamber VC. A driving unit may be disposed between the electrostatic chuck 100 and the vacuum chamber VC. The electrostatic chuck 100 may move in the first direction DR1 or in a direction opposite to the first direction DR1 by an operation of the driving unit. For example, the electrostatic chuck 100 may move vertically by the operation of the driving unit.

The electrostatic chuck 100 may include a housing, and multiple electrodes disposed inside the housing. The electrodes may include first and second electrodes having different polarities. For example, the first electrodes may have a positive polarity (+), and the second electrodes may have a negative polarity (−).

The electrodes may be alternately arranged in a second direction DR2 or a third direction DR3. For example, the electrodes may be alternately arranged in the second direction DR2. In an embodiment, the electrodes may be alternately arranged in the third direction DR3. Each of the second and third directions DR2 and DR3 may intersect the first direction DR1. The second direction DR2 and the third direction DR3 may intersect each other. For example, the first direction DR1, the second direction DR2, and the third direction DR3 may be perpendicular to each other.

The electrostatic chuck 100 may overlap the whole substrate SUB in a plan view. Accordingly, the substrate SUB may be prevented from sagging in the direction opposite to the first direction DR1 while deposition materials provided from the deposition source 400 are deposited.

The electrostatic chuck 100 may chuck or dechuck the substrate SUB by an electrostatic force. The electrostatic chuck 100 may be a bipolar electrostatic chuck or a monopolar electrostatic chuck. In a case of a bipolar electrostatic chuck 100, the electrostatic chuck 100 may include two electrode plates. In case that a voltage is applied between the two electrode plates, the substrate SUB may be chucked. In a case of a monopolar electrostatic chuck 100, the electrostatic chuck 100 may include only one electrode plate. In case that a voltage is applied between the electrode plate and the substrate SUB, the substrate SUB may be chucked. After a deposition process is performed, the electrostatic chuck 100 may dechuck the substrate SUB.

The electrostatic chuck 100 may have a multilayer structure. For example, the electrostatic chuck 100 may include a base layer, an insulating layer, and an electrode. The base layer may include a material for providing a chucking surface capable of chucking or dechucking the substrate SUB. For example, the base layer may include ceramic, aluminum, titanium, stainless steel, alumina, yttrium oxide, aluminum nitride, or the like. These may be used alone or in combination with each other. The insulating layer may include a material having high heat resistance and high chemical stability. For example, the insulating layer may include yttrium oxide, alumina, or the like. As a voltage is applied to the electrode, the substrate SUB may be chucked or dechucked by the electrostatic chuck 100. However, the electrostatic chuck 100 according to embodiments of the disclosure is not limited thereto.

Multiple holders 200 may be disposed between the electrostatic chuck 100 and the mask frame 320. The holders 200 may hold the substrate SUB. According to an embodiment, each of the holders 200 may include first connection parts 220, second connection parts 240, and third connection parts 260.

The first connection parts 220 may be connected to a side of the electrostatic chuck 100. Accordingly, the electrostatic chuck 100 and the holders 200 may move simultaneously.

The second connection parts 240 may be connected to the first connection parts 220 in a direction intersecting an extension direction of the first connection part 220. For example, the second connection parts 240 may be perpendicularly connected to the first connection parts 220.

The third connection parts 260 may be connected to the second connection parts 240 in a direction intersecting an extension direction of the second connection part 240. For example, the second connection parts 240 and the third connection parts 260 may be perpendicularly connected to each other.

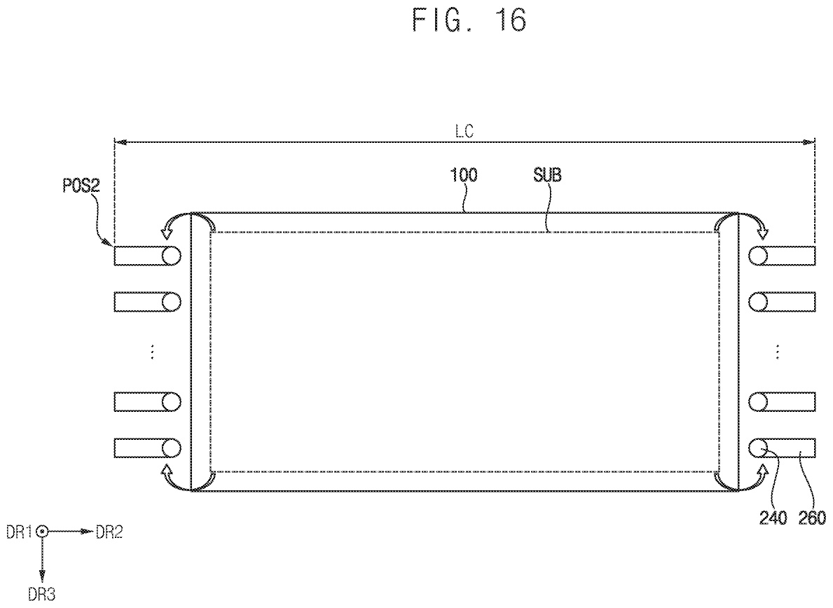

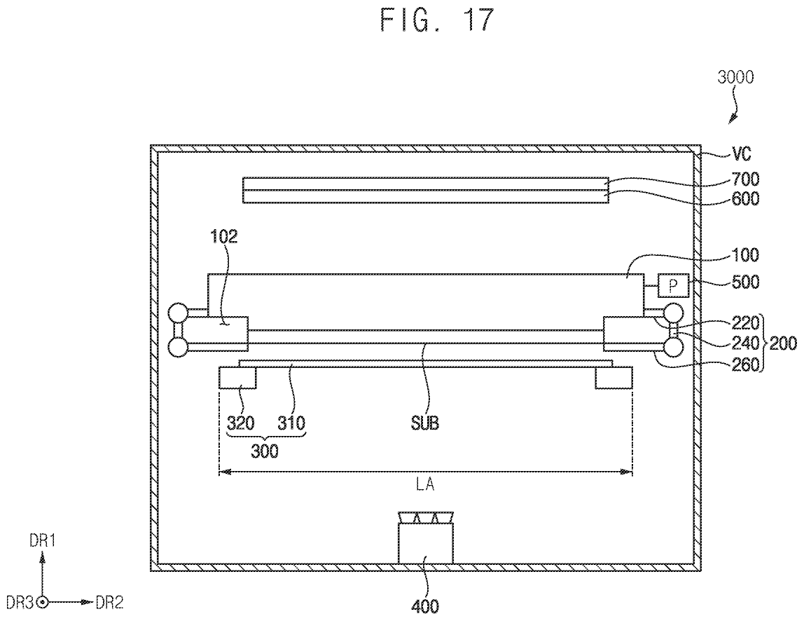

The third connection parts 260 may rotationally move to a first position (e.g., a first position POS1 of FIG. 15) overlapping the substrate SUB or a second position (e.g., a second position POS2 of FIG. 16) spaced apart from the substrate SUB.

According to an embodiment, each of the third connection parts 260 may rotate about the extension direction of the second connection part 240. For example, each of the third connection parts 260 may rotate about the first direction DR1. Accordingly, the third connection parts 260 may overlap the substrate SUB at the first position in a plan view, or may be offset from the substrate SUB at the second position in a plan view.

According to another embodiment, the second connection parts 240 and the third connection parts 260 may rotate simultaneously about the extension direction of the second connection part 240. For example, the second connection parts 240 and the third connection parts 260 may rotate about the first direction DR1. Accordingly, the third connection parts 260 may overlap the substrate SUB at the first position in a plan view, or may be offset from the substrate SUB at the second position in a plan view. However, the disclosure is not limited thereto, and the third connection parts 260 may move in various ways to the second position that does not overlap the substrate SUB.

The third connection parts 260 may linearly move in the extension direction of the second connection part 240. For example, the third connection parts 260 may linearly move in the first direction DR1 or the direction opposite to the first direction DR1. However, the electrostatic chuck 100 is not limited thereto. The holders 200 may include a larger number of connection parts, and the connection parts may linearly or rotationally move.

The mask unit 300 may be disposed under the electrostatic chuck 100. For example, the mask unit 300 may be disposed under the holders 200.

The mask unit 300 may include a mask 310 and a mask frame 320. The mask unit 300 may be disposed under the electrostatic chuck 100. For example, the mask unit 300 may be disposed under the holders 200.

The mask 310 may be disposed on the mask frame 320.

Multiple holes may be formed on the mask 310. The deposition materials may be provided to the substrate SUB through the holes.

The mask 310 may define multiple cell regions 312. The cell regions 312 may be spaced apart from each other. The cell regions 312 may be arranged in one of the second direction DR2 or the third direction DR3, or may be arranged in a matrix form in the second direction DR2 or the third direction DR3.

The mask frame 320 may be disposed under the electrostatic chuck 100. For example, the mask frame 320 may be disposed under the holders 200.

The mask frame 320 may have an edge 322 having a flat top surface.

The mask frame 320 may support the mask 310. An opening 324 may be formed on the mask frame 320. The mask 310 may be disposed on the mask frame 320 such that the holes formed on the mask 310 overlap the opening 324 formed in the mask frame 320 in a thickness direction of the mask frame 320.

The mask frame 320 may include a metal. For example, the metal may include stainless steel, an invar alloy, nickel, cobalt, or the like. These may be used alone or in combination with each other.

The deposition source 400 may be disposed under the mask unit 300.

The deposition source 400 may include a deposition material, a heating source, and at least one nozzle.

The deposition source 400 may provide a material to be deposited on the substrate SUB. According to an embodiment, the deposition material may include a metal, an organic material, an inorganic material, or the like. For example, in case that the deposition material is an organic material, an organic material layer may be formed through a deposition process.

The deposition material may include a vaporization material or a sublimation material. In case that the deposition material is a vaporization material, the heating source may be disposed adjacent to the deposition material. The heating source may heat and vaporize the deposition material. In an embodiment, the heating source may be omitted.

The nozzle may be disposed over the deposition material. The nozzle may spray the deposition material in the first direction DR1. At least one nozzle may be provided. In an embodiment, multiple nozzles may be provided. The nozzles may be spaced apart from each other in the second direction DR2 or the third direction DR3. A number, an interval, a shape, and the like of the nozzles may vary depending on the deposition material.

A power supply 500 may be connected to the electrostatic chuck 100. For example, the power supply 500 may be connected to the electrodes. For example, the power supply 500 may include a terminal defined as a positive electrode and another terminal defined as a negative electrode. The first electrodes may be connected to the terminal, so that the first electrodes may have a positive polarity. The second electrodes may be connected to the another terminal, so that the second electrodes may have a negative polarity. The electrostatic chuck 100 may receive a voltage from the power supply 500 to generate electrostatic force.

The cooling plate 600 may be disposed over the electrostatic chuck 100. A driving unit may be disposed between the cooling plate 600 and the vacuum chamber VC. The cooling plate 600 may move in the first direction DR1 or the direction opposite to the first direction DR1 by an operation of the driving unit. For example, the cooling plate 600 may move vertically by the operation of the driving unit. The driving unit of the cooling plate 600 and the driving unit of the electrostatic chuck 100 may be provided separately from each other. Accordingly, deposition quality deterioration caused by vibrations of the cooling plate 600 may be prevented.

The cooling plate 600 may include a cooling material. For example, the cooling plate 600 may include a cooling gas. The cooling gas may be argon gas, hydrogen gas, or the like. These may be used alone or in combination with each other. The cooling plate 600 may be independently driven to control a temperature of the electrostatic chuck 100. The temperature of an entire area of the chucking surface of the electrostatic chuck 100 may be controlled to be constant, so that stain of the substrate SUB caused by a temperature deviation may be prevented.

The magnetic plate 700 may be disposed over the cooling plate 600. A driving unit may be disposed between the magnetic plate 700 and the vacuum chamber VC. The driving unit of the cooling plate 600 and the driving unit of the magnetic plate 700 may be a same device, or may be separate devices. In case that the driving unit of the cooling plate 600 and the driving unit of the magnetic plate 700 are separate devices, the driving unit of the cooling plate 600 and the driving unit of the magnetic plate 700 may be controlled simultaneously. In an embodiment, the driving unit of the cooling plate 600 and the driving unit of the magnetic plate 700 may be controlled separately from each other. Since the driving unit of the magnetic plate 700 and the driving unit of the electrostatic chuck 100 are provided separately from each other, deposition quality deterioration caused by vibrations of the magnetic plate 700 may be prevented.

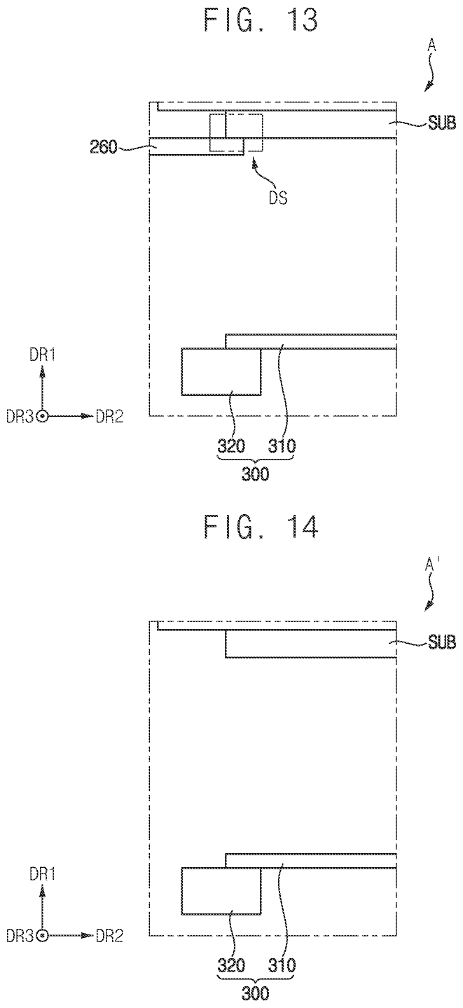

According to an embodiment, the substrate loading device 1000 may include the third connection parts 260 that are rotationally movable, so that the holders 200 including the third connection parts 260 and the substrate SUB may not overlap each other. For example, the third connection parts 260 may be disposed at the second position offset from the substrate SUB. Accordingly, a dead space (e.g., see a dead space DS of FIG. 13), which is a portion of the substrate SUB overlapping the holders 200 in a plan view, may not exist, so that an effective area of a cell arrangement may be increased.

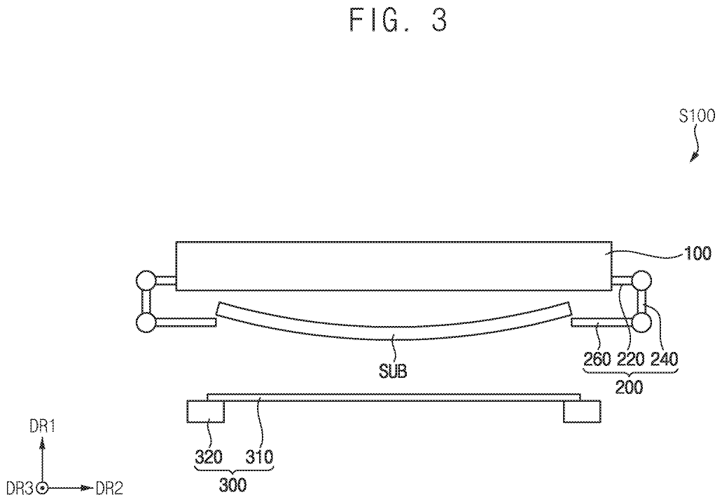

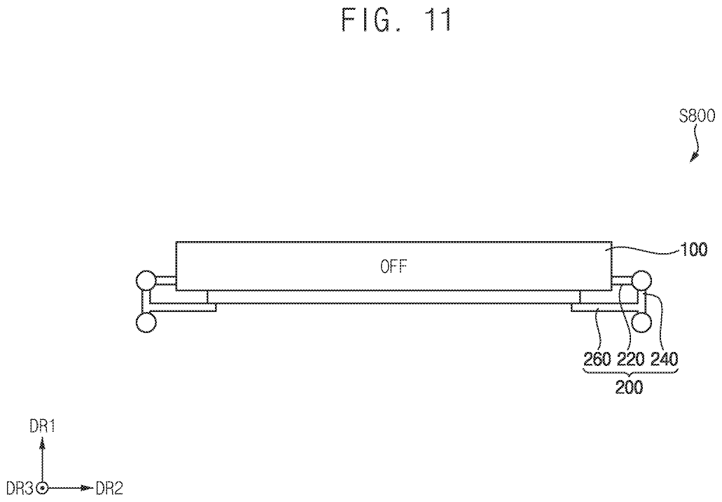

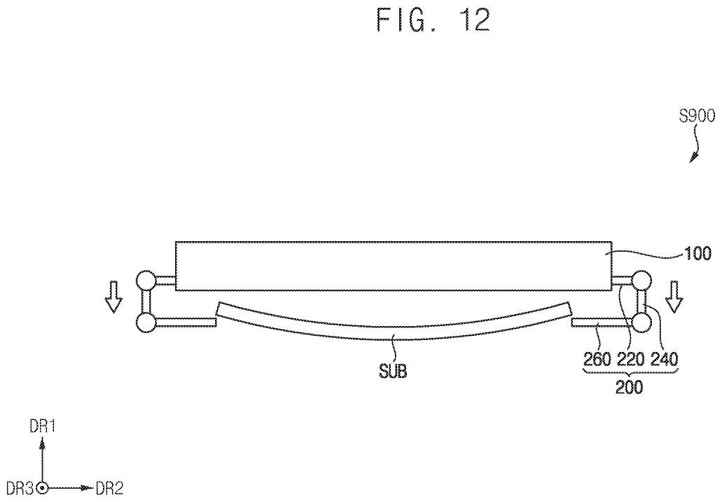

FIGS. 3 to 12 are schematic cross-views for describing a substrate loading method using the substrate loading device according to an embodiment of the disclosure. For example, the substrate loading device 1000 described with reference to FIG. 1 may be used to perform a substrate loading method that will be described with reference to FIGS. 3 to 12.

Referring to FIGS. 3 to 12, the substrate loading method may include: holding a substrate SUB by multiple holders 200 (S100); moving the substrate SUB to make close contact with an electrostatic chuck 100 by the holders 200 (S200); chucking the substrate SUB by the electrostatic chuck 100 (S300); moving third connection parts 260 included in the holders 200 from a first position overlapping the substrate SUB to a second position offset from the substrate SUB (S400); aligning the substrate SUB with a mask frame 320 (S500); performing a treatment process on the substrate SUB (S600); moving the third connection parts 260 from the second position to the first position (S700); dechucking the substrate SUB by the electrostatic chuck 100 (S800); and holding the substrate SUB by the holders 200 (S900). Hereinafter, redundant descriptions of the substrate loading device 1000 described above with reference to FIGS. 1 and 2 will be omitted or simplified.

As shown in FIGS. 3 to 5, the holders 200 may hold the substrate SUB (S100), and the holders 200 may move the substrate SUB to make close contact with the electrostatic chuck 100 (S200, S200′).

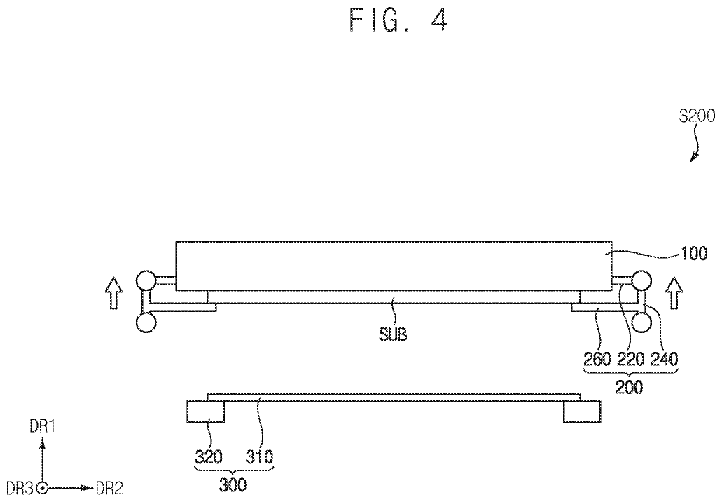

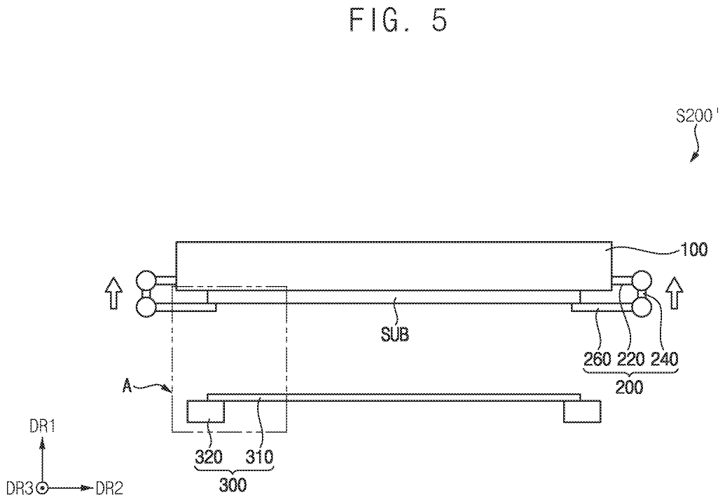

For example, as shown in FIG. 3, the third connection parts 260 of the holders 200 may hold the substrate SUB (S100). As shown in FIGS. 4 and 5, the holders 200 may move the substrate SUB to make close contact with the electrostatic chuck 100 (S200 and S200′).

According to an embodiment, as shown in FIG. 4, the third connection parts 260 of the holders 200 may linearly move in the extension direction of the second connection part 240. In an embodiment, the third connection part 260 and the second connection part 240 may be integral with each other. For example, the third connection parts 260 may move in the first direction DR1 or the direction opposite to the first direction DR1 with the second connection parts 240. For example, as the third connection parts 260 ascend with the second connection parts 240, the substrate SUB seated on the third connection parts 260 may make close contact with the electrostatic chuck 100 (S200).

According to another embodiment, as shown in FIG. 5, the third connection parts 260 and the second connection parts 240 of the holders 200 may linearly move simultaneously in the extension direction of the second connection part 240. The third connection parts 260 and the second connection parts 240 may move simultaneously in the first direction DR1 or the direction opposite to the first direction DR1. For example, as the second connection parts 240 ascend, the third connection parts 260 may also ascend, so that the substrate SUB seated on the third connection parts 260 may make close contact with the electrostatic chuck 100 (S200′).

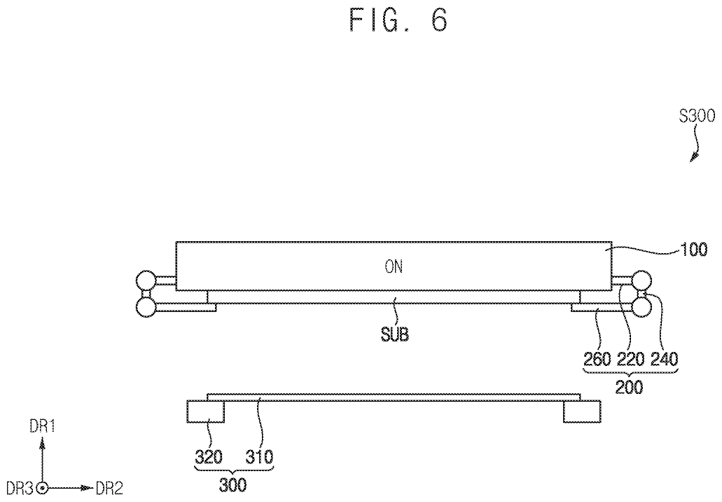

As shown in FIG. 6, the electrostatic chuck 100 may chuck the substrate SUB (S300).

As described above with reference to FIGS. 1 and 2, the electrostatic chuck 100 may chuck the substrate SUB by using electrostatic force. Accordingly, even in case that the holders 200 do not physically support the substrate SUB, the substrate SUB may not fall in the direction opposite to the first direction DR1.

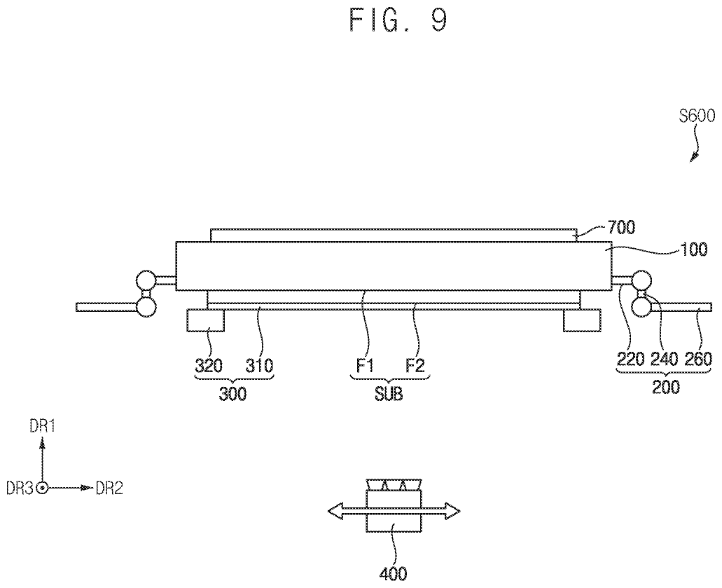

According to an embodiment, in case that a first surface F1 (see FIG. 9) of the substrate SUB is chucked by the electrostatic chuck 100, a second surface F2 of the substrate SUB facing the first surface F1 may overlap the mask unit 300 in a plan view. For example, the second surface F2 of the substrate SUB may overlap a portion of the mask frame 320 in a plan view.

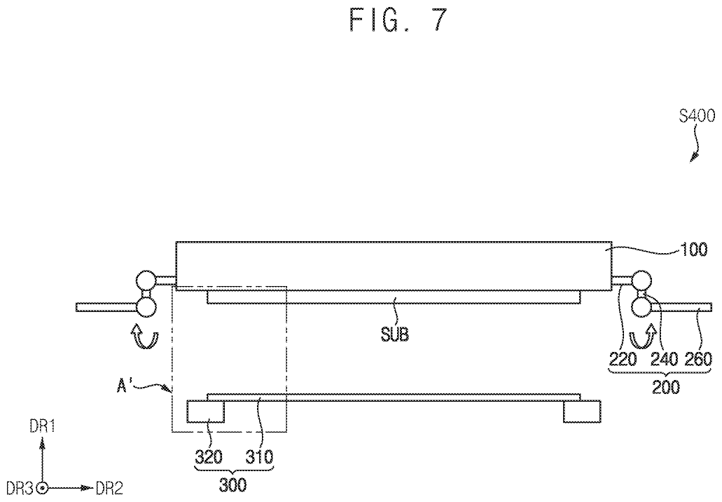

As shown in FIG. 7, the third connection parts 260 of the holders 200 may be moved from the first position overlapping the substrate SUB to the second position spaced apart from the substrate SUB (S400).

According to an embodiment, as described above with reference to FIGS. 1 and 2, each of the third connection parts 260 may rotate about the extension direction of the second connection part 240. For example, as the third connection parts 260 rotate about the first direction DR1, the third connection parts 260 may move to the second position. Accordingly, the third connection parts 260 may move to the second position that does not overlap the substrate SUB.

According to another embodiment, as described above with reference to FIGS. 1 and 2, the second connection parts 240 and the third connection parts 260 may rotate simultaneously about the extension direction of the second connection part 240. For example, the second connection parts 240 and the third connection parts 260 may rotate simultaneously about the first direction DR1. Accordingly, the third connection parts 260 may be disposed at the second position.

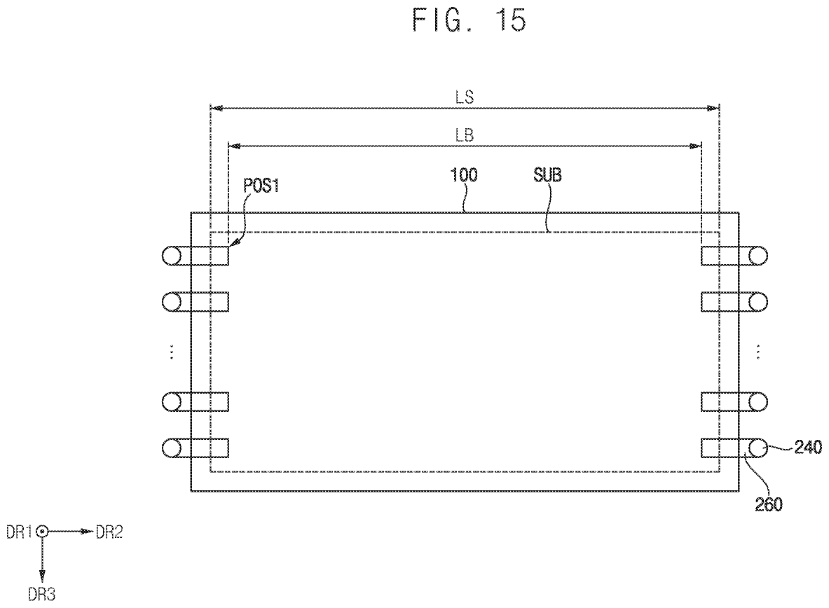

After the third connection parts 260 move to the second position, the third connection parts 260 may not overlap the mask frame 320 in a plan view. Since the third connection parts 260 do not overlap the mask frame 320, the dead space, which is a portion of the substrate SUB overlapping the holders 200 in a plan view, may be reduced. The above configuration will be described in detail below with reference to FIGS. 13 and 14.

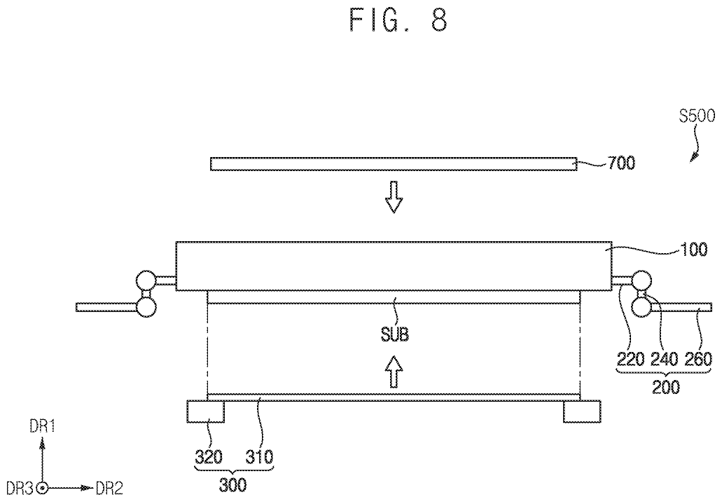

As shown in FIGS. 8 and 9, the substrate SUB may be aligned with the mask frame 320 (S500), and the treatment process may be performed on the substrate SUB (S600). As described above with reference to FIGS. 1 and 2, the mask frame 320 may be disposed under the holders 200, and may include an edge 322 having a flat top surface.

According to an embodiment, the third connection parts 260 may be moved to the second position that does not overlap the substrate SUB (S400), the substrate SUB may be aligned with the mask frame 320 (S500), and the treatment process may be performed on the substrate SUB (S600). While the electrostatic chuck 100 chucks the substrate SUB, it may be unnecessary to support the substrate SUB by the holders 200, so that the holders 200 may be moved to the second position that does not overlap the substrate SUB, and the treatment process may be performed.

According to another embodiment, the substrate SUB may be aligned with the mask frame 320 (S500), the third connection parts 260 may be moved to the second position that does not overlap the substrate SUB (S400), and the treatment process may be performed on the substrate SUB (S600). Even in case that the substrate SUB is aligned with the mask frame 320, a gap may exist.

Therefore, after the substrate SUB is aligned with the mask frame 320, the holders 200 may be moved.

According to an embodiment, the treatment process may be performed on the substrate SUB while the first surface F1 of the substrate SUB is chucked by the electrostatic chuck 100 (S600). The second surface F2 of the substrate SUB facing the first surface F1 may face the mask unit 300. For example, the electrostatic chuck 100 may be disposed under the magnetic plate 700. The substrate SUB may be disposed under the electrostatic chuck 100. The mask unit 300 may be disposed under the substrate SUB. The deposition source 400 may be disposed under the mask unit 300.

According to an embodiment, the treatment process may be performed on the substrate SUB while the second surface F2 of the substrate SUB faces the mask frame 320 (S600). The holders 200 may not overlap the mask frame 320 in a plan view during the treatment process. For example, the third connection parts 260 may not overlap the mask frame 320 in a plan view during the treatment process. Since the holders 200 are disposed at the second position spaced apart from the substrate SUB, an effective area of a cell arrangement may be increased. According to an embodiment, in the aligning of the substrate SUB and the mask frame 320, the mask frame 320 may move in the first direction DR1 until an upper surface of the mask frame 320 contacts the second surface F2 of the substrate SUB. For example, during the treatment process, the upper surface of the mask frame 320 and the second surface F2 of the substrate SUB may contact each other. Since the substrate SUB makes close contact with the mask frame 320, manufacturing quality of a display device may be improved.

According to an embodiment, the performing of the treatment process on the substrate SUB (S600) may include depositing deposition materials, which are provided from a deposition source 400, on the substrate SUB. However, the disclosure is not limited thereto, and the substrate loading method according to embodiments of the disclosure may be used in various processes such as cutting and polishing using a laser.

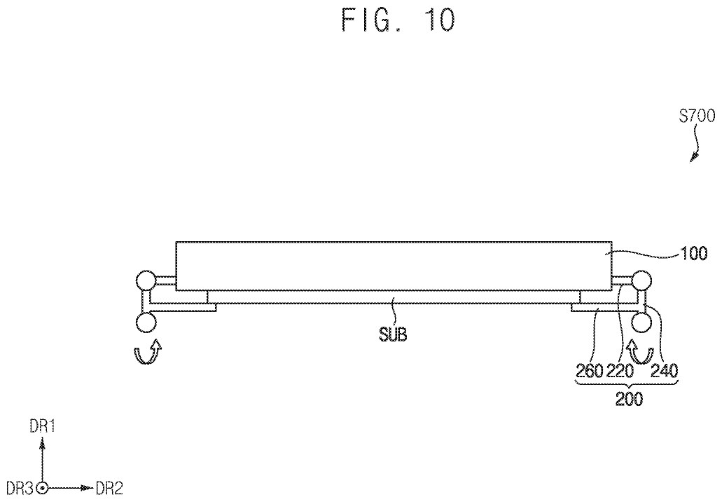

As shown in FIGS. 10 to 12, the third connection parts 260 may be moved from the second position to the first position (S700), the electrostatic chuck 100 may dechuck the substrate SUB (S800), and the holders 200 may hold the substrate SUB (S900).

FIG. 13 is an enlarged view showing region A of FIG. 5, FIG. 14 is an enlarged view showing region A′ of FIG. 7, and FIGS. 15 and 16 are plan views for describing a first position and a second position of the third connection parts. For convenience of description, the first connection parts 220 connected to the electrostatic chuck 100 have been omitted.

Referring to FIGS. 13 to 16, the third connection parts 260 of the holders 200 may hold the substrate SUB. Top surfaces of the third connection parts 260 may face the substrate SUB, and bottom surfaces of the third connection parts 260 may face the mask frame 320.

In a case of a substrate loading device in which a groove is formed on a mask frame 320, third connection parts 260 of the holders 200 may be seated in grooves formed on the mask frame 320, and a treatment process may be performed on a substrate SUB. For example, as shown in FIG. 9, the treatment process may be a deposition process.

The substrate loading device 1000 according to an embodiment of the disclosure may be configured such that the edge 322 of the mask frame 320 is flat. For example, the substrate loading device 1000 according to the embodiment of the disclosure may be configured such that the groove is not formed on the edge 322 of the mask frame 320. In order to remove the dead space, which is a portion of the substrate SUB overlapping the holders 200 in a plan view, the third connection parts 260 of the holders 200 may move to the second position so as not to overlap the mask frame 320. As described above, the third connection parts 260 may rotate about the first direction DR1, so that the third connection parts 260 may not overlap the mask frame 320 in a plan view during the treatment process.

At the first position, the dead space, which is a portion of the substrate SUB overlapping the holders 200 in a plan view, for example, the third connection parts 260 of the holder 200, may exist. On the contrary, at the second position, the third connection parts 260 may be spaced apart from the substrate SUB, so that the dead space, which is a portion of the substrate SUB overlapping the holders 200 in a plan view, may not exist. Therefore, the deposition materials may be deposited over the whole substrate SUB.

As shown in FIG. 15, the third connection parts 260 may be disposed at the first position POS1. In case that the third connection parts 260 are disposed at the first position POS1, a distance LB between ends of the third connection parts 260 facing each other may be less than a width LS of the substrate SUB in a direction respective third connection parts 260 facing each other. The third connection parts 260 may face each other in an extension direction of the third connection parts 260 in case that the third connection parts 260 are at the first position POS1. Accordingly, the third connection parts 260 may hold the substrate SUB.

As shown in FIGS. 1 and 16, the third connection parts 260 may be disposed at the second position POS2. In case that the third connection parts 260 are disposed at the second position POS2, a distance LC between the ends of the third connection parts 260 facing each other may be the longest. The third connection parts 260 may face each other in the extension direction of the third connection part 260. For example, the distance LC between the ends of the third connection parts 260 facing each other may be greater than the width of the mask frame.

According to an embodiment, the substrate loading method may be configured such that the third connection parts 260 may be rotationally moved to the second position spaced apart from the substrate SUB. Accordingly, during the deposition process, the substrate SUB and the mask frame 320 may make close contact with each other, so that the manufacturing quality of the display device may be improved.

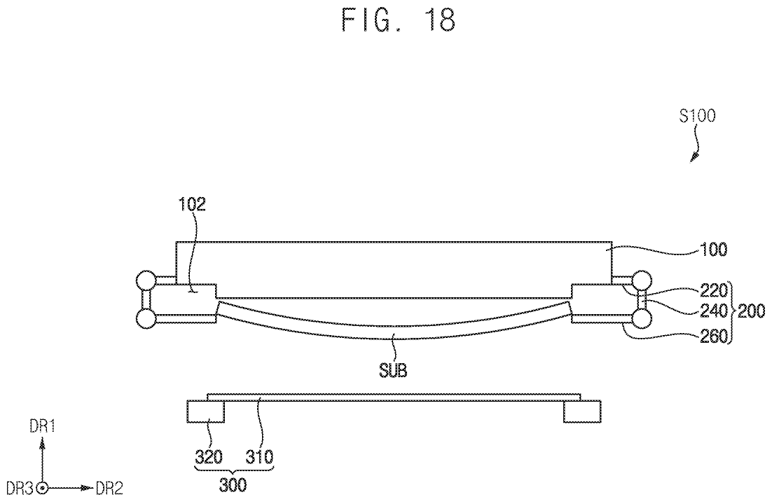

FIG. 17 is a schematic cross-sectional view showing a substrate loading device according to another embodiment of the disclosure.

Referring to FIG. 17, a substrate loading device 3000 may include an electrostatic chuck 100, a mask unit 300, a deposition source 400, a cooling plate 600, and a magnetic plate 700 disposed in a vacuum chamber VC. Hereinafter, redundant descriptions overlapping the substrate loading device 1000 and the substrate loading method using the substrate loading device 1000 described above with reference to FIGS. 1 to 16 will be omitted or simplified.

The electrostatic chuck 100 may have a chucking surface. The chucking surface may be defined by the first direction DR1 and the second direction DR2. In a plan view, an area of the electrostatic chuck 100 (e.g., an area of the chucking surface) may be greater than an area of the substrate SUB. Since the area of the electrostatic chuck 100 is greater than the area of the substrate SUB, the electrostatic chuck 100 may chuck the substrate SUB more stably.

According to an embodiment, a groove 102 may be formed on the electrostatic chuck 100. The groove 102 may overlap the holders 200 disposed at the second position. For example, the groove 102 may overlap the third connection parts 260 disposed at the second position.

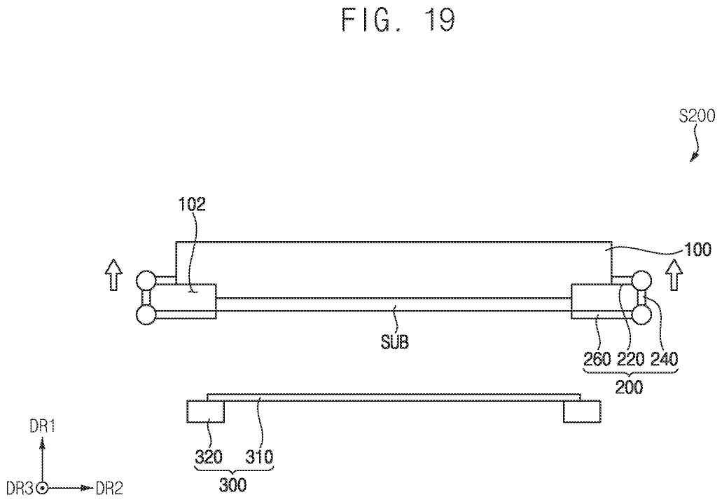

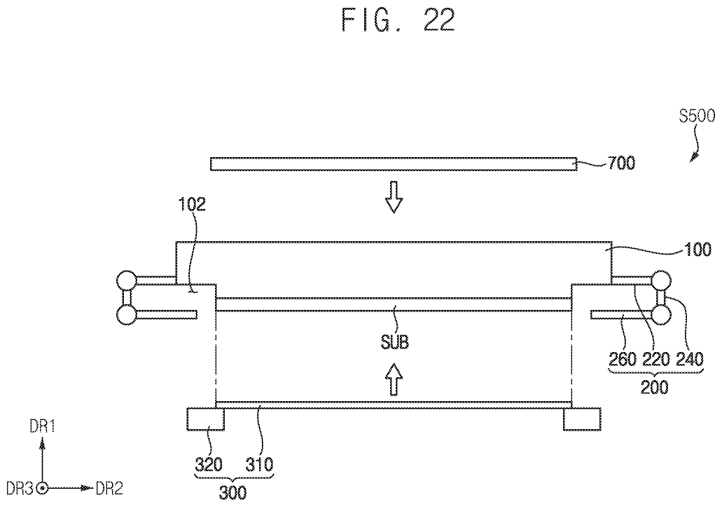

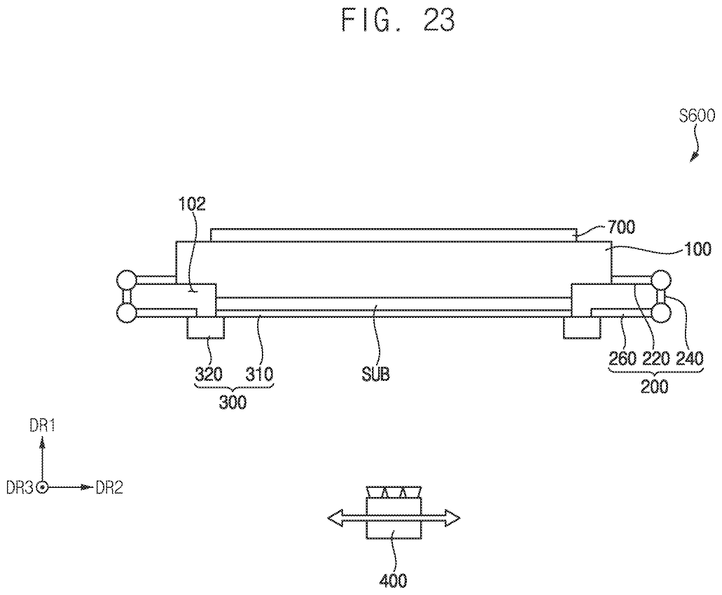

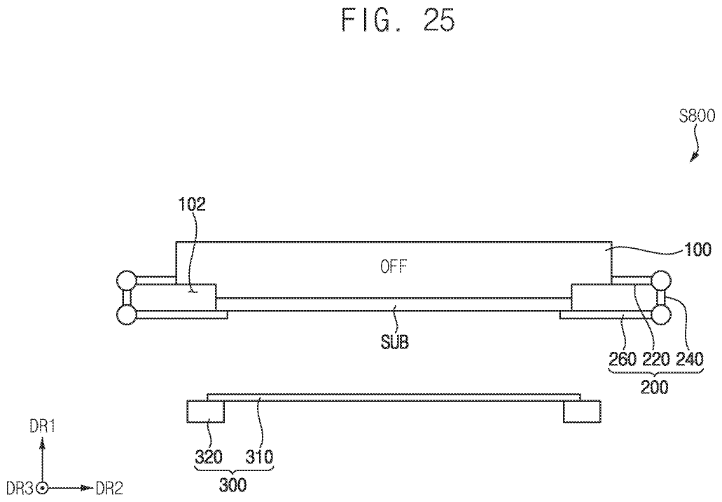

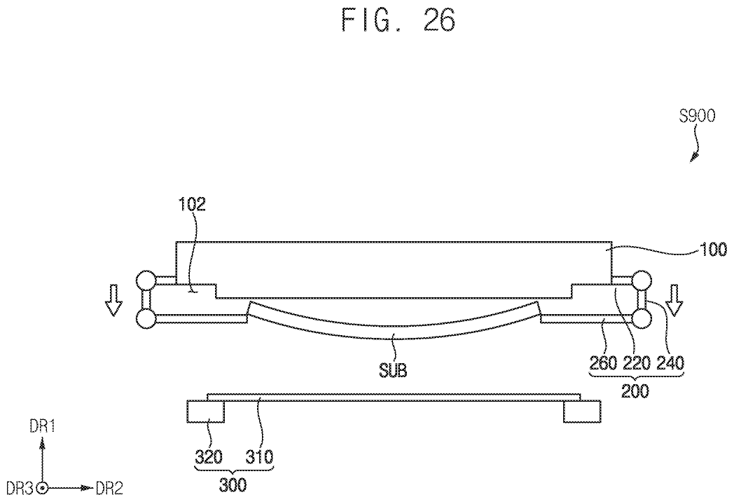

According to another embodiment, the groove 102 may not be formed on the electrostatic chuck 100. A size of the electrostatic chuck 100 may be sufficiently large so that the holders 200 disposed at the second position may not overlap the mask frame 320. The size of the electrostatic chuck 100 and the second position will be described in detail below with reference to FIGS. 18 to 28.

The holders 200 may be disposed between the electrostatic chuck 100 and the mask frame 320. The holders 200 may hold the substrate SUB. According to an embodiment, each of the holders 200 may include first connection parts 220, second connection parts 240, and third connection parts 260.

The first connection parts 220 may be connected to a side of the electrostatic chuck 100. Accordingly, the electrostatic chuck 100 and the holders 200 may move simultaneously.

The second connection parts 240 may be connected to the first connection parts 220 in a direction intersecting an extension direction of the first connection part 220. For example, the second connection parts 240 may be perpendicularly connected to the first connection parts 220.

The third connection parts 260 may be connected to the second connection parts 240 in a direction intersecting an extension direction of the second connection part 240. For example, the second connection parts 240 and the third connection parts 260 may be perpendicularly connected to each other.

The third connection parts 260 may linearly move to the first position overlapping the substrate SUB or the second position spaced apart from the substrate SUB.

According to an embodiment, the third connection parts 260 may linearly move in the direction intersecting the extension direction of the second connection part 240. For example, each of the third connection parts 260 may linearly move in the second direction DR2 or the third direction DR3. However, the disclosure is not limited thereto, and positions of the third connection parts 260 may be changed as the second connection parts 240 are tilted. The third connection parts 260 may linearly move to a third position as the second connection parts 240 are tilted. Similar to the second position, the third position may be a position in which the third connection parts 260 do not overlap the substrate SUB.

According to an embodiment, the substrate loading device 3000 may include the third connection parts 260 connected to the electrostatic chuck 100 having a greater area than the substrate SUB so as to be linearly movable, so that the holders 200 including the third connection parts 260 and the substrate SUB may not overlap each other. For example, the third connection parts 260 may be disposed at the second position spaced apart from the substrate SUB. Accordingly, the dead space, which is a portion of the substrate SUB overlapping the holders 200 in a plan view, may not exist, so that the effective area of the cell arrangement may be increased.

FIGS. 18 to 26 are views for describing a substrate loading method using the substrate loading device according to an embodiment of the disclosure. For example, the substrate loading device 3000 described with reference to FIG. 17 may be used to perform a substrate loading method that will be described with reference to FIGS. 18 to 26.

Referring to FIGS. 18 to 26, the substrate loading method may include: holding a substrate SUB by multiple holders 200 (S100); moving the substrate SUB to make close contact with an electrostatic chuck 100 by the holders 200 (S200); chucking the substrate SUB by the electrostatic chuck 100 (S300); moving third connection parts 260 included in the holders 200 from a first position overlapping the substrate SUB to a second position spaced apart from the substrate SUB (S400); aligning the substrate SUB with a mask frame 320 (S500); performing a treatment process on the substrate SUB (S600); moving the third connection parts 260 from the second position to the first position (S700); dechucking the substrate SUB by the electrostatic chuck 100 (S800); and holding the substrate SUB by the holders 200 (S900).

As shown in FIGS. 18 to 20, the holders 200 may hold the substrate SUB (S100), the holders 200 may move the substrate SUB to make close contact with the electrostatic chuck 100 (S200), and the electrostatic chuck 100 may chuck the substrate SUB (S300).

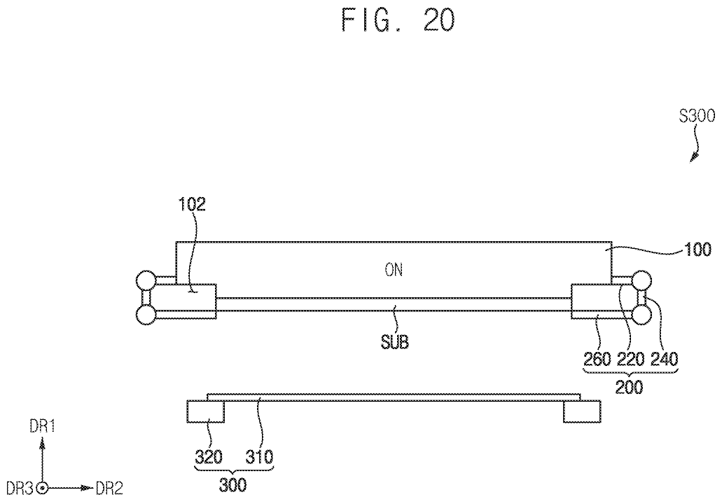

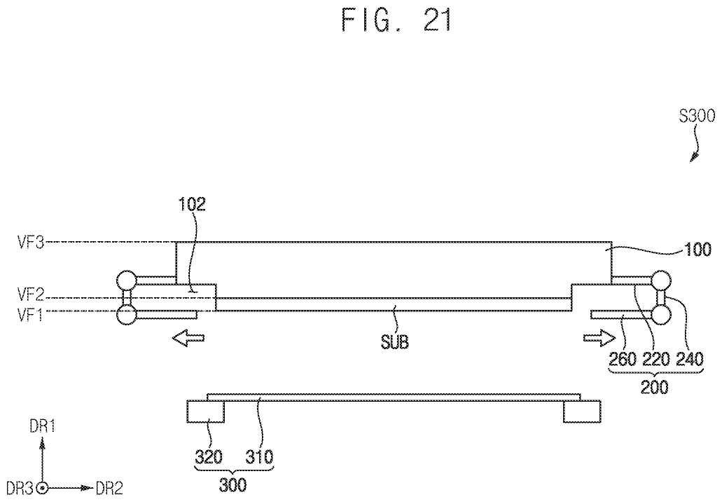

For example, as shown in FIG. 18, the third connection parts 260 of the holders 200 may hold the substrate SUB (S100). As shown in FIG. 19, the holders 200 may move the substrate SUB to make close contact with the electrostatic chuck 100 (S200). As shown in FIG. 20, the electrostatic chuck 100 may chuck the substrate SUB by using the electrostatic force. Accordingly, even when the holders 200 do not physically support the substrate SUB, the substrate SUB may not fall in the direction opposite to the first direction DR1.

According to an embodiment, as shown in FIG. 4, the third connection parts 260 of the holders 200 may move in the first direction DR1 or the direction opposite to the first direction DR1 with the second connection parts 240. According to another embodiment, as shown in FIG. 5, the third connection parts 260 and the second connection parts 240 of the holders 200 may move simultaneously in the first direction DR1 or the direction opposite to the first direction DR1.

As shown in FIGS. 21 to 23, the third connection parts 260 of the holders 200 may move from the first position overlapping the substrate SUB to the second position spaced apart from the substrate SUB (S400). As described above with reference to FIGS. 8 and 9, the moving of the third connection parts 260 to the second position (S400) may be performed before the aligning of the substrate SUB with the mask frame 320 (S500), or may be performed before the performing of the treatment process on the substrate SUB (S600).

According to an embodiment, the moving of the third connection parts 260 to the second position may include linearly moving the third connection parts 260 in the extension direction of the third connection part 260. After the third connection parts 260 are linearly moved in the extension direction of the third connection part 260, the third connection parts 260 may linearly move in the extension direction of the second connection part 240. For example, the third connection parts 260 may linearly move in a direction opposite to the second direction DR2 or a direction opposite to the third direction DR3. In an embodiment, an elastic body may be inserted between the third connection parts 260 and the second connection parts 240. In case that an external force is applied to the elastic body, a distance between the third connection parts 260 facing each other may be increased, and in case that the external force applied to the elastic body is removed, the distance between the third connection parts 260 facing each other may be decreased. In another embodiment, a latch may be provided between the second connection parts 240 and the third connection parts 260, and sliding rails may be provided on the third connection parts 260. Accordingly, the third connection parts 260 may slidably move along the sliding rails. Accordingly, the distance between the third connection parts 260 facing each other may be increased or decreased. As the third connection parts 260 linearly move in the second direction DR2 or the third direction DR3, the third connection parts 260 may be offset from the substrate SUB in a plan view. In case that the third connection parts 260 are disposed in the second position, a distance between the third connection parts 260 may be greater than a width of the mask frame 320 in a direction corresponding third connection parts 260 facing each other.

According to an embodiment, while the substrate SUB is chucked by the electrostatic chuck 100, the third connection parts 260 may linearly move in the extension direction of the third connection part 260, and the third connection parts 260 may be seated in the groove 102 formed on the electrostatic chuck 100. For example, the third connection parts 260 may be disposed between a top surface VF2 (see FIG. 21) of the substrate SUB and a top surface VF3 (see FIG. 21) of the electrostatic chuck 100. However, the disclosure is not limited thereto. In another embodiment, the third connection parts 260 may be disposed between a bottom surface VF1 of the substrate SUB and the top surface VF2 of the substrate SUB and not disposed in the groove 102. For example, the third connection parts 260 may be disposed adjacent to side surfaces of the substrate SUB.

Accordingly, the dead space, which is a portion of the substrate SUB overlapping the holders 200 in a plan view, may be eliminated. According to an embodiment, in the aligning of the substrate SUB and the mask frame 320, the mask frame 320 may move in the first direction DR1 until an upper surface of the mask frame 320 contacts the second surface F2 of the substrate SUB. For example, during the treatment process, the upper surface of the mask frame 320 and the second surface F2 of the substrate SUB may contact each other. Since the holders 200 are not disposed between the substrate SUB and the mask frame 320, the mask frame 320 may make close contact with the substrate SUB. Accordingly, the manufacturing quality of the display device may be improved.

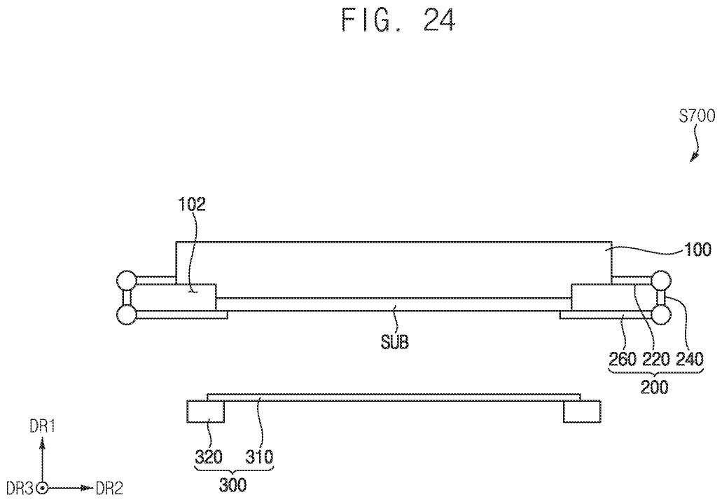

As shown in FIGS. 24 to 26, the third connection parts 260 may be moved from the second position to the first position (S700), the electrostatic chuck 100 may dechuck the substrate SUB (S800), and the holders 200 may hold the substrate SUB (S900).

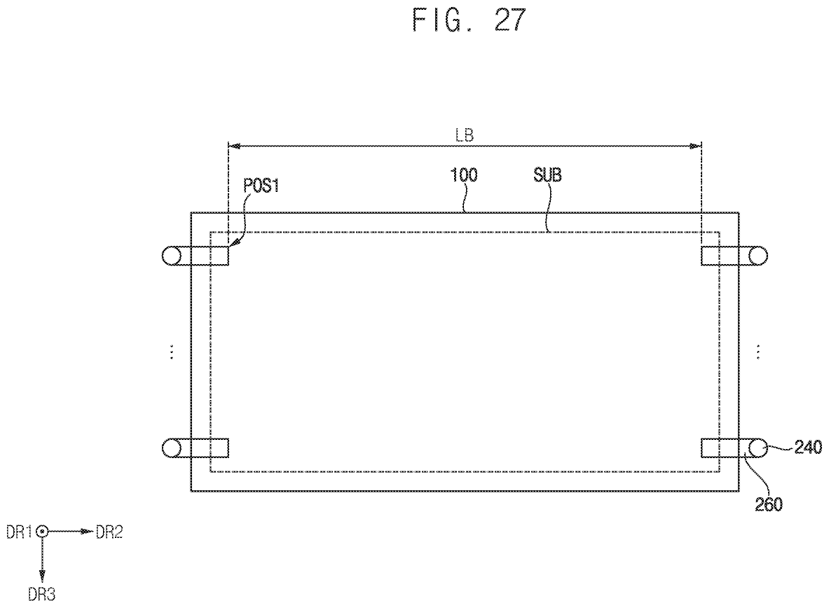

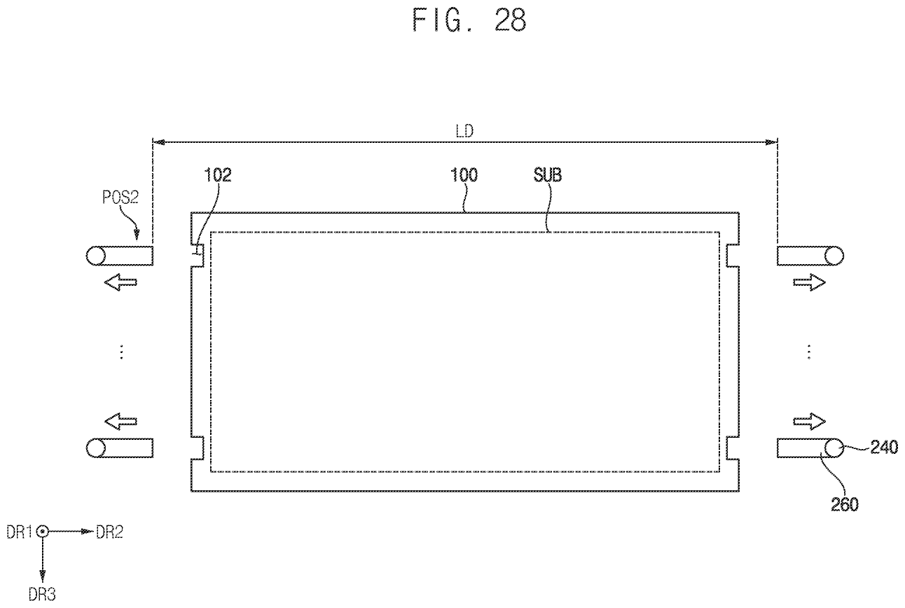

FIGS. 27 and 28 are plan views for describing a first position and a second position of the third connection parts. For convenience of description, the first connection parts 220 connected to the electrostatic chuck 100 have been omitted.

As described above with reference to FIGS. 13 to 16, in a case of a substrate loading device in which a groove is formed on a mask frame 320, third connection parts 260 of the holders 200 may be seated in the grooves formed on the mask frame 320, and a treatment process may be performed on a substrate SUB. However, the disclosure is not limited thereto, and according to another embodiment, the substrate loading device 3000 may be configured such that the edge 322 of the mask frame 320 has a flat top surface.

For example, the substrate loading device 3000 may be configured such that the groove is not formed on the edge 322 of the mask frame 320. In order to remove the dead space, which is a portion of the substrate SUB overlapping the holders 200 in a plan view, the third connection parts 260 of the holders 200 may move to the second position to offset from the mask frame 320. As described above, the third connection parts 260 may rotate about the first direction DR1, so that the third connection parts 260 may be offset from the mask frame 320 in a plan view.

At the first position, the dead space, which is a portion of the substrate SUB overlapping the holders 200 in a plan view, may exist. For example, at the first position, the dead space in which the third connection parts 260 and the substrate SUB overlap each other may exist. On the contrary, at the second position, the third connection parts 260 may be spaced apart from the substrate SUB, so that the dead space, which is a portion of the substrate SUB overlapping the holders 200 in a plan view, may not exist. Therefore, the deposition materials may be deposited over the whole substrate SUB.

As shown in FIG. 27, the third connection parts 260 may be disposed at the first position POS1. In case that the third connection parts 260 are disposed at the first position POS1, a distance LB between ends of the third connection parts 260 facing each other may be less than a width of the substrate SUB in a direction respective third connection parts 260 facing each other (e.g., the width LS of the substrate SUB of FIG. 15). Accordingly, the third connection parts 260 may hold the substrate SUB. In case that the third connection parts 260 are disposed at the first position POS1, the distance LB between the ends of the third connecting parts 260 facing each other may be less than a width of the mask frame 320 in a direction respective third connection parts 260 facing each other. Accordingly, the substrate SUB and the mask frame 320 may make close contact with each other.

As shown in FIG. 28, the third connection parts 260 may be disposed at the second position POS2. In case that the third connection parts 260 are disposed at the second position POS2, a distance LD between the ends of the third connection parts 260 facing each other may be the longest. For example, the distance LD between the ends of the third connection parts 260 facing each other in the extension direction of the third connection part 260 may be greater than the width of the mask frame 320 in a direction respective third connection parts 260 facing each other.

The substrate loading method according to the embodiments of the disclosure may be configured such that the third connection parts 260 may be linearly moved to the second position spaced apart from the substrate SUB. Accordingly, during the treatment process, the substrate SUB and the mask frame 320 may make close contact with each other, so that the manufacturing quality of the display device may be improved.

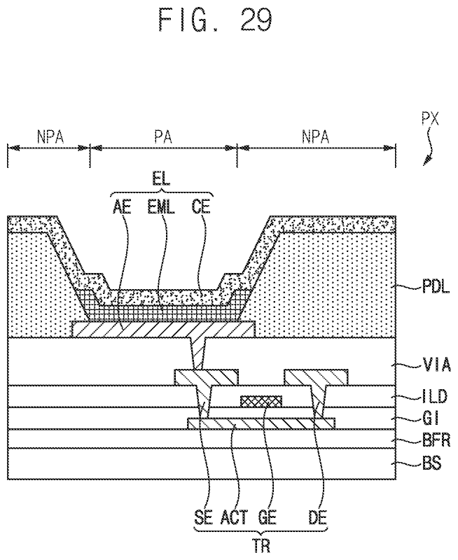

FIG. 29 is a schematic cross-sectional view showing a pixel on which a deposition process is completed by using the substrate loading method according to the embodiments of the disclosure.

Referring to FIG. 29, the pixel PX may include a base substrate BS, a buffer layer BFR, a transistor TR, a gate insulating layer GI, an interlayer insulating layer ILD, a via insulating layer VIA, a light emitting element EL, and a pixel defining layer PDL. The transistor may include an active layer ACT, a gate electrode GE, a source electrode SE, and a drain electrode DE. The light emitting element EL may include a first electrode AE, a light emitting layer EML, and a second electrode CE. The display area may include an emission area PA and a non-emission area NPA. The transistor TR and the light emitting element EL may be disposed in the light emission area PA. The non-emission area NPA may surround the light emission area PA in a plan view. Here, plan view may mean when viewed in the first direction DR1.

The base substrate BS may include glass, quartz, plastic, or the like. In an embodiment, the base substrate BS may have flexible, bendable, or rollable characteristics.

The buffer layer BFR may be disposed on the base substrate BS. The buffer layer BFR may include an inorganic insulating material. For example, the buffer layer BFR may include silicon oxide, silicon nitride, silicon oxynitride, or the like. The buffer layer BFR may serve to block impurities so that the active layer ACT of the transistor TR is not damaged by the impurities diffused from the base substrate BS.

The active layer ACT may be disposed on the buffer layer BFR. In an embodiment, the active layer ACT may include a silicon semiconductor. For example, the active layer ACT may include amorphous silicon or polycrystalline silicon. In another embodiment, the active layer ACT may include an oxide semiconductor. For example, the active layer ACT may include zinc oxide, zinc-tin oxide, zinc-indium oxide, indium oxide, titanium oxide, indium-gallium-zinc oxide, indium-zinc-tin oxide, or the like.

The gate insulating layer GI may be disposed on the active layer ACT. The gate insulating layer GI may include an inorganic insulating material. For example, the gate insulating layer GI may include silicon oxide, silicon nitride, silicon oxynitride, titanium oxide, tantalum oxide, or the like. The gate insulating layer GI may serve to electrically insulate the active layer ACT and the gate electrode GE from each other.

The gate electrode GE may be disposed on the gate insulating layer GI. The gate electrode GE may include a conductive material. For example, the gate electrode GE may include a metal, an alloy, a conductive metal oxide, a transparent conductive material, or the like. A gate signal may be applied to the gate electrode GE. The gate signal may turn on or turn off the transistor TR to adjust electrical conductivity of the active layer ACT.

The interlayer insulating layer ILD may be disposed on the gate electrode GE. The interlayer insulating layer ILD may include an organic insulating material and/or an inorganic insulating material. The interlayer insulating layer ILD may serve to electrically insulate the source electrode SE and drain electrode DE from the gate electrode GE.

The source electrode SE and the drain electrode DE may be disposed on the interlayer insulating layer ILD. Each of the source electrode SE and the drain electrode DE may include a conductive material. For example, each of the source electrode SE and the drain electrode DE may include a metal, an alloy, a conductive metal oxide, a transparent conductive material, or the like. Each of the source electrode SE and the drain electrode DE may electrically contact the active layer ACT through a contact hole passing through the interlayer insulating layer ILD and the gate insulating layer GI.

The via insulating layer VIA may be disposed on the source electrode SE and the drain electrode DE. The via insulating layer VIA may include an organic insulating material. For example, the via insulating layer VIA may include a poly-acrylic resin, a polyimide resin, an acrylic resin, or the like. Accordingly, a top surface of the via insulating layer VIA may be substantially flat.

The first electrode AE may be disposed on the via insulating layer VIA. The first electrode AE may include a conductive material. For example, the first electrode AE may include a metal, an alloy, a conductive metal oxide, a transparent conductive material, or the like. The first electrode AE may electrically contact the source electrode SE or the drain electrode DE through a contact hole penetrating the via insulating layer VIA. In an embodiment, the first electrode AE may be referred to as an anode electrode.

The pixel defining layer PDL may be disposed on the first electrode AE. The pixel defining layer PDL may include an organic insulating material. For example, the pixel defining layer PDL may include a polyacryl-based compound or a polyimide-based compound. The pixel defining layer PDL may partition the emission area PA of each of the pixels PX. The pixel defining layer PDL may include a pixel opening exposing the first electrode AE.

The light emitting layer EML may be disposed on the first electrode AE in the pixel opening. The light emitting layer EML may include an organic light emitting material. In an embodiment, the light emitting layer EML may have a multi-layer structure including various functional layers. In an embodiment, the light emitting layer EML may include at least one of a hole injection layer, a hole transport layer, an electron transport layer, and an electron injection layer.

The second electrode CE may be disposed on the light emitting layer EML and may cover the pixel defining layer PDL. In an embodiment, the second electrode CE may be referred to as a cathode electrode.

In an embodiment, the light emitting layer EML may be formed by depositing deposition materials on the first electrode AE. The substrate loading devices (e.g., the substrate loading devices 1000 and 3000 of FIGS. 1 and 17) and the substrate loading methods may be used.

However, the disclosure is not limited thereto, and a layer formed of the deposition materials is not limited as long as the layer is formed by the deposition process. For example, the deposition process may include a sputtering process and the like. The layer that may be deposited may be the functional layers such as the hole transport layer and the electron transport layer, or may be a capping layer, an encapsulation layer, and the like disposed on the second electrode CE. The deposition materials may include an organic material and/or an inorganic material.

The substrate loading device according to embodiments of the disclosure may be applied to a process of manufacturing a display device included in a computer, laptop, mobile phone, smart phone, smart pad, PMP, PDA, MP3 player, and the like.

The above description is an example of technical features of the disclosure, and those skilled in the art to which the disclosure pertains will be able to make various modifications and variations. Thus, the embodiments of the disclosure described above may be implemented separately or in combination with each other.

Therefore, the embodiments disclosed in the disclosure are not intended to limit the technical spirit of the disclosure, but to describe the technical spirit of the disclosure, and the scope of the technical spirit of the disclosure is not limited by these embodiments. The protection scope of the disclosure should be interpreted by the following claims, and it should be interpreted that all technical spirits within the equivalent scope are included in the scope of the disclosure.

What is claimed is:

1. A substrate loading device comprising:
an electrostatic chuck that chucks a substrate;
a mask frame disposed under the electrostatic chuck, and including an edge having a flat top surface; and
a plurality of holders disposed between the electrostatic chuck and the mask frame, each of the plurality of holders including:
a first connection part connected to a side of the electrostatic chuck;
a second connection part connected to the first connection part and extending in a direction intersecting an extension direction of the first connection part; and
a third connection part connected to the second connection part, extending in a direction intersecting an extension direction of the second connection part, and rotationally moving between a first position overlapping the substrate in a thickness direction of the substrate and a second position spaced apart from the substrate.

2. The substrate loading device of claim 1, wherein the third connection part rotates about the extension direction of the second connection part.

3. The substrate loading device of claim 1, wherein
the third connection part and the second connection part are integral with each other, and
the second connection part rotates about the extension direction of the second connection part.

4. The substrate loading device of claim 1, wherein the third connection part linearly moves in the extension direction of the second connection part.

5. The substrate loading device of claim 1, wherein, in case that a first surface of the substrate is chucked by the electrostatic chuck,
a second surface of the substrate facing the first surface overlaps the mask frame in the thickness direction, and
the third connection part is disposed at the second position not overlapping the mask frame in the thickness direction.

6. A substrate loading device comprising:
an electrostatic chuck that chucks a substrate, and having an area that is greater than an area of the substrate in a plan view; and
a plurality of holders disposed under the electrostatic chuck, each of the plurality of holders including:
a first connection part connected to a side of the electrostatic chuck;
a second connection part connected to the first connection part and extending in a direction intersecting an extension direction of the first connection part; and
a third connection part connected to the second connection part, extending in a direction intersecting an extension direction of the second connection part, and linearly moving between a first position overlapping the substrate in a thickness direction of the substrate and a second position spaced apart from the substrate.

7. The substrate loading device of claim 6, wherein
the electrostatic chuck includes a groove on a surface facing the substrate adjacent to the plurality of holders, and
the groove overlaps the third connection part disposed at the second position in the thickness direction.

8. The substrate loading device of claim 6, wherein the third connection part linearly moves in the direction intersecting the extension direction of the second connection part.

9. The substrate loading device of claim 6, further comprising:
a mask frame disposed under the plurality of holders and including an edge having a flat top surface.

10. The substrate loading device of claim 9, wherein, in case that a first surface of the substrate is chucked by the electrostatic chuck,
a second surface of the substrate facing the first surface overlaps the mask frame in the thickness direction, and
the third connection part is disposed at the second position not overlapping the mask frame in the thickness direction.

11. A substrate loading method comprising:
holding a substrate by a third connection part of a plurality of holders, which is disposed at a first position overlapping the substrate in a thickness direction of the substrate, each of the plurality of holders including a first connection part connected to a side of an electrostatic chuck, a second connection part connected to the first connection part and extending in a direction intersecting an extension direction of the first connection part, and the third connection part connected to the second connection part and extending in a direction intersecting an extension direction of the second connection part;
moving the substrate to closely contact the electrostatic chuck by the plurality of holders;
chucking the substrate by the electrostatic chuck;
moving the third connection part from the first position to a second position spaced apart from the substrate;
moving the third connection part from the second position to the first position;
dechucking the substrate by the electrostatic chuck; and
holding the substrate by the plurality of holders.

12. The substrate loading method of claim 11, wherein the moving of the third connection part from the first position to the second position includes rotating the third connection part about the extension direction of the second connection part.

13. The substrate loading method of claim 12, wherein after the rotating of the third connection part, a distance between ends of third connection parts of the plurality of holders facing each other in an extension direction of the third connection part is longest.

14. The substrate loading method of claim 11, further comprising:
between the chucking of the substrate by the electrostatic chuck and the moving of the third connection part from the first position to the second position, aligning the substrate with a mask frame disposed under the plurality of holders and including an edge having a flat top surface.

15. The substrate loading method of claim 11, further comprising:
between the moving of the third connection part from the first position to the second position and the moving of the third connection part from the second position to the first position,
aligning the substrate with a mask frame disposed under the plurality of holders and including an edge having a flat top surface; and
performing a treatment process on the substrate.

16. The substrate loading method of claim 15, wherein, in the performing of the treatment process on the substrate,
a first surface of the substrate is chucked by the electrostatic chuck,
a second surface of the substrate facing the first surface overlaps the mask frame in the thickness direction, and
the third connection part does not overlap the mask frame in the thickness direction.

17. The substrate loading method of claim 15, wherein the performing of the treatment process on the substrate includes depositing a deposition material, which is provided from a deposition source disposed under the mask frame, on the substrate.

18. The substrate loading method of claim 14, wherein the moving of the third connection part from the first position to the second position includes linearly moving the third connection part in an extension direction of the third connection part so that a distance between ends of third connection parts of the plurality of holders facing each other in the extension direction of the third connection part is greater than a width of the mask frame in the extension direction of the third connection part.

19. The substrate loading method of claim 18, wherein the moving of the third connection part from the first position to the second position further includes linearly moving the third connection part in the extension direction of the second connection part after the linearly moving of the third connection part in the extension direction of the third connection part.

20. The substrate loading method of claim 19, further comprising:
between the linearly moving of the third connection part in the extension direction of the second connection part and the aligning of the substrate with the mask frame, seating the third connection part in grooves formed on the electrostatic chuck.
